(19) United States
(12) Patent Application Publication
(10) Pub. No.: US 2026/0206220 A1
(43) Pub. Date: Jul. 16, 2026

(54) VERTICAL NOR MEMORY STRINGS AND METHOD FOR FABRICATION THEREOF

(71) Applicant: SUNRISE MEMORY CORPORATION, San Jose, CA (US)

(72) Inventors: Vinod Purayath, Sedona, AZ (US); Kenta Ohama, Tokyo (JP); Yosuke Nosho, Tokyo (JP)

(21) Appl. No.: 19/557,032

(22) Filed: Mar. 4, 2026

Related U.S. Application Data
(63) Continuation of application No. 17/559,101, filed on Dec. 22, 2021, now Pat. No. 12,604,468.
(60) Provisional application No. 63/139,435, filed on Jan. 20, 2021.

(51) Int. Cl. H10B 43/20; H10B 43/40

(52) U.S. Cl. CPC H10B 43/20; H10B 43/40

(57) ABSTRACT

A process for forming a VNOR memory string includes: providing multiple composite layers of an insulator layer and a sacrificial layer; excavating first and second shafts in the composite layers; lining the sidewalls of the shafts with a second insulator; filling the shafts with a first semiconductor material of a first conductivity type; excavating a slot through the composite layers between the first and second shafts; lining the slot conformally with a second semiconductor material of a second conductivity type opposite the first conductivity type; filling the slot with a third insulator; creating a trench through the multiple composite layers; removing the sacrificial layer through the trench; lining the space between the adjacent insulator layers with a conformal storage layer; and filling the space between the adjacent insulator layers with a conductor.

### CROSS REFERENCE TO RELATED APPLICATIONS

This application is a continuation of co-pending U.S. Patent Application No. 17/559,101, entitled VERTICAL NOR MEMORY STRINGS AND METHOD FOR FABRICATION THEREOF, filed December 22, 2021, which relates to and claims priority of U.S. provisional patent application, serial no. 63/139,435, entitled “Vertical NOR Flash Thin film Transistor Strings and Fabrication Thereof,” filed on January 20, 2021, which applications are hereby incorporated by reference herein in their entireties.

### FIELD OF THE INVENTION

The present invention relates to high-density memory circuits. In particular, the present invention relates to 3-dimensional arrays of vertical NOR memory strings and fabrication processes for such 3-dimensional arrays.

### BACKGROUND OF THE INVENTION

U.S. Patent 10,790,023 (“the ‘023 patent”), entitled “Three-dimensional vertical NOR Flash Thin film Transistor Strings,” filed on July 3, 2019 and issued on September 29, 2020, discloses a 3-dimensional array of thin-film storage transistors formed above a planar surface of a semiconductor substrate. The ‘023 patent’s storage transistors are organized as NOR memory strings, arranged in rows and columns along orthogonal directions (the “horizontal” directions) that are substantially parallel to the planar surface of the semiconductor substrate. Each of the ‘023 patent’s NOR memory strings include numerous storage transistors sharing a common bit line and a common source line, with the gate electrode of each storage transistor being controlled by a different word line. In examples illustrated in the ‘023 patent’s, each NOR memory string has its common bit line and its common word line provided as polysilicon pillars that are lengthwise aligned substantially normal to the planar surface of the semiconductor substrate (the “vertical” direction), while the word lines are stacked along the vertical direction, each word line extending lengthwise along one of the horizontal directions. In this detailed description, NOR memory strings with the ‘023 patent’s configuration of common bit line, common word line and word lines are referred to as “VNOR memory strings.”

U.S. Patent 10,748,629 (“the ‘629 patent”), serial no. 16/107,118, entitled “Capacitive-Coupled Non-Volatile Thin-Film Transistor Strings in Three-Dimensional Arrays,” discloses NOR memory strings with horizontal common bit lines, horizontal common source lines and vertical word lines. In this detailed description, NOR memory strings with the ‘629 patent’s configuration of common bit line, common word line and word lines are referred to as “HNOR memory strings.”

VNOR memory strings and HNOR memory strings are both very high density non-volatile or quasi-volatile memory circuits. In this context, non-volatile memory circuits have data retention times in order of tens of years and beyond, while quasi-volatile memory circuits have data retention times between seconds and years. Efficient, reliable and high-yield manufacturing processes for manufacturing these memory circuits are desired.

### SUMMARY OF THE INVENTION

According to one embodiment of the present invention, a process for forming a VNOR memory string over a planar surface of a semiconductor substrate, includes: (a) providing multiple composite layers, each composite layer comprising an insulator layer and a sacrificial layer; (b) excavating first and second shafts in the composite layers; (c) lining the sidewalls of the first and second shafts with a second insulator; (d) filling the first and second shafts with a first semiconductor material of a first conductivity type; (e) excavating a slot through the composite layers between the first and second shafts, the excavating removing a portion of the first semiconductor material in each of the first and second shafts; (f) lining the slot conformally with a second semiconductor material of a second conductivity type opposite the first conductivity type; (g) filling the slot with a third insulator; (h) creating a trench through the multiple composite layers; (i) removing the sacrificial layer through the trench to create a space between adjacent insulator layers in the composite layers; (j) lining the space between the adjacent insulator layers with a conformal storage layer; and (k) filling the space between the adjacent insulator layers with a conductor. The insulator layers in the composite layers, the second insulator, and the third insulator each include silicon oxide. The first semiconductor material and the second semiconductor material may be n⁺ polysilicon and p⁻ polysilicon, respectively. The conductor may be metallic tungsten (W) in conjunction with a titanium nitride (TiN) liner.

The process of may further include: (a) providing an isolation layer over the first and second shafts; and forming a conductor-filled via in the isolation layer, the conductor-filled via contacting one of the first and second shafts. The process may further provide on the isolation layer a conductor that is in contact with the conductor-filled via. To avoid shorting to the top conductor layer in the composite layers, prior to forming conductor-filled via, the process may provide an etch-stop layer above the top conductor layer.

According to one embodiment of the present invention, a VNOR memory string includes: (a) first and second pillars embedded in multiple composite layers, each composite layer comprising an insulator layer and a conductor layer, the first and second pillars each comprising a first semiconductor material of a first conductivity; (b) a second semiconductor layer -- either intrinsic or of a second conductivity type opposite the first conductivity type -- on the outside of third pillar also embedded in the composite layers, the third pillar contacting both the first and second pillars; and (c) a storage layer provided between the second semiconductor layer and each of the conductor layer in the composite layers. The third pillar may include a second insulator layer enclosed by the second semiconductor layer. The first semiconductor material and the second semiconductor material may be n+ polysilicon and p⁻ polysilicon, respectively. The conductor layers of the composite layers each include metallic tungsten (W) in conjunction with a titanium nitride (TiN) liner.

The present invention is better understood upon consideration of the detailed description below, in conjunction with the accompanying drawings.

### BRIEF DESCRIPTION OF THE DRAWINGS

FIG. 1 is a top view of modular circuits 101-1 and 101-2 formed above a planar surface of a semiconductor substrate, each modular circuit including numerous VNOR memory strings, in accordance with one embodiment of the present invention.

FIGS. 2(a), 2(b), 2(c), 2(d) 2(e), 2(f), 2(g), 2(h), 2(i) and 2(j) illustrate a process for fabricating modular circuits 101-1 and 101-2, according to one embodiment of the present invention.

FIGS. 2(e-1), 2(f-1), 2(g-1), 2(h-1), 2(i-1) and 2(j-1) and FIGS. 2(j-1) show the alternative structures for the structures shown in FIGS. 2(e) to 2(j).

FIG. 3(a) shows unit cell 301, including four VNOR memory strings, according to an alternative embodiment of the present invention.

FIG. 3(b) shows top view of modular circuit 302 of FIG. 3(a), formed using unit cell 301 as a building block, in accordance with the alternative embodiment of the present invention.

For clarity, a Cartesian coordinate system is adopted to help orient these figures. Under this Cartesian coordinate system, the Z-direction is substantially normal to the planar surface of the semiconductor substrate, and the X- and Y-directions are substantially orthogonal to each other and each substantially orthogonal to the Z-direction (i.e., each substantially parallel to the planar surface of the semiconductor substrate).

To facilitate cross-reference across figures, like elements in the figures are assigned like reference numerals. DETAILED DESCRIPTION OF THE INVENTION

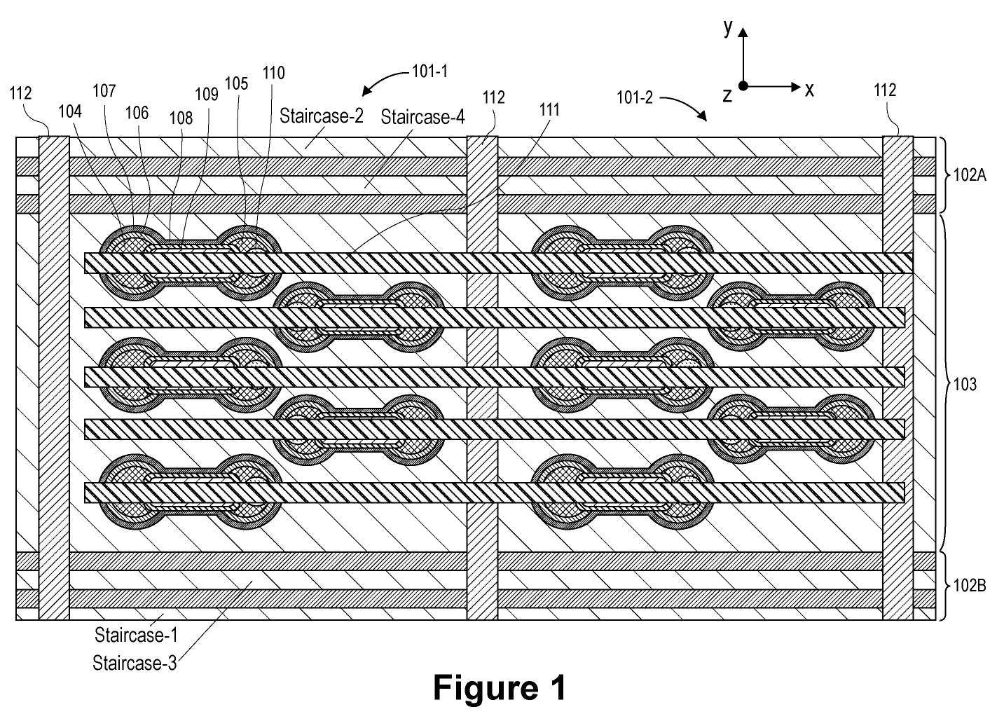

FIG. 1 is a top view (i.e., in an X-Y plane) of modular circuits 101-1 and 101-2 formed above a planar surface of a semiconductor substrate, each modular circuit including numerous VNOR memory strings, in accordance with one embodiment of the present invention. As shown in FIG. 1, modular circuits 101-1 and 101-2, each bounded by isolation trenches (“slit trenches”) 112 along the X-direction, and each including array portion 103 and staircase portions 102A and 102B. In this context, array portion 103 includes the numerous VNOR memory strings, while staircase portions 102A and 102B each include steps that allow access to the storage transistors of the VNOR memory strings through via connections which connect from one or more interconnection conductor layers to the word lines that control the storage transistors of each VNOR memory string. In one embodiment, staircase portion 102A has steps that allow via connections to word lines on even-numbered steps (2^{nd}, 4^{th}, 6^{th}, … steps from the planar surface), while staircase portion 102B allow via connections to word lines on odd-numbered steps (1^{st}, 3^{rd}, 5^{th}, 7^{th}, … steps from the planar surface). FIG. 1 shows, merely for illustrative purpose, two staggered columns of VNOR memory strings (i.e., one column being offset from the other column by a given distance, such as 130 nm.) In FIG. 1, each of modular circuits 101-1 and 101-2 are implemented by a unit cell as a building block, which unit cell may be 160-nm wide along the Y-direction and 380 nm wide along the X-direction. Each VNOR memory string in the unit cell includes n⁺ polysilicon pillars 104 and 105, each extending along the Z-direction down to the bottom of 3-dimensional array, at an insulation layer above the planar surface of the semiconductor substrate. Of course, both the number of VNOR memory strings and their respective dimensions are provided for illustrative purpose only. Any implementation may have any suitable number of VNOR memory strings in array portion 103 and any suitable dimensions for elements in each VNOR memory string.

Conformal insulator layer 106 (e.g. silicon oxide) may be provided on the sidewalls of n⁺ polysilicon pillars 104 and 105. Insulator-filled channel slot 109 (e.g., silicon oxide), extending along the Z-direction down to bottom of the 3-dimensional array, is provided between n⁺ polysilicon pillars 104 and 105. Conformally deposited p⁻ polysilicon layer 108 -- which is designated to become channel regions of the storage transistors in the VNOR memory string -- is deposited over insulator-filled channel slot 109. Conformally deposited storage layer (e.g., an oxide-nitride-oxide (“ONO”) charge-trapping layer) 107 is provided over conformally deposited p⁻ polysilicon layer 108. The oxide-nitride-oxide triple layer provides a tunneling layer, a charge-trapping layer and a blocking layer, respectively. One of n⁺ polysilicon pillars 104 and 105 is electrically contacted through 80-nm wide via connection 110 by a 50-nm wide conductor 111 in an interconnection conductor layer. Conductor 111 provides a global bit line to connect multiple selected n⁺ polysilicon pillars 105. In each VNOR memory string, the contacted one of n⁺ polysilicon pillars 104 and 105 serves as the common bit line, while the non-contacted one of n⁺ polysilicon pillars 104 and 105 serves as the common source line.

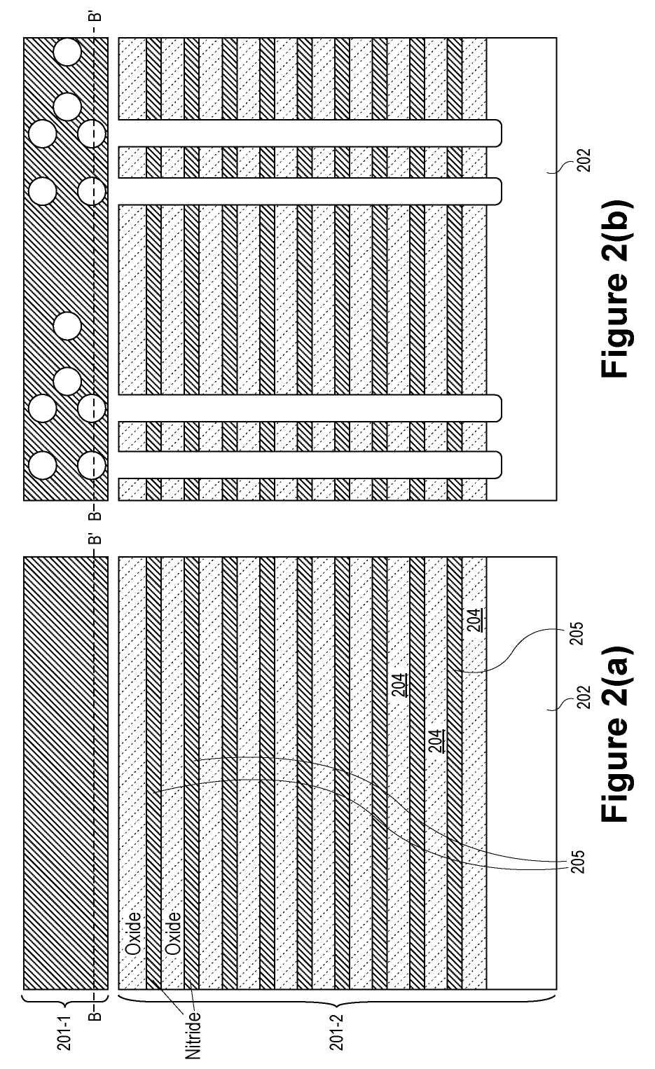

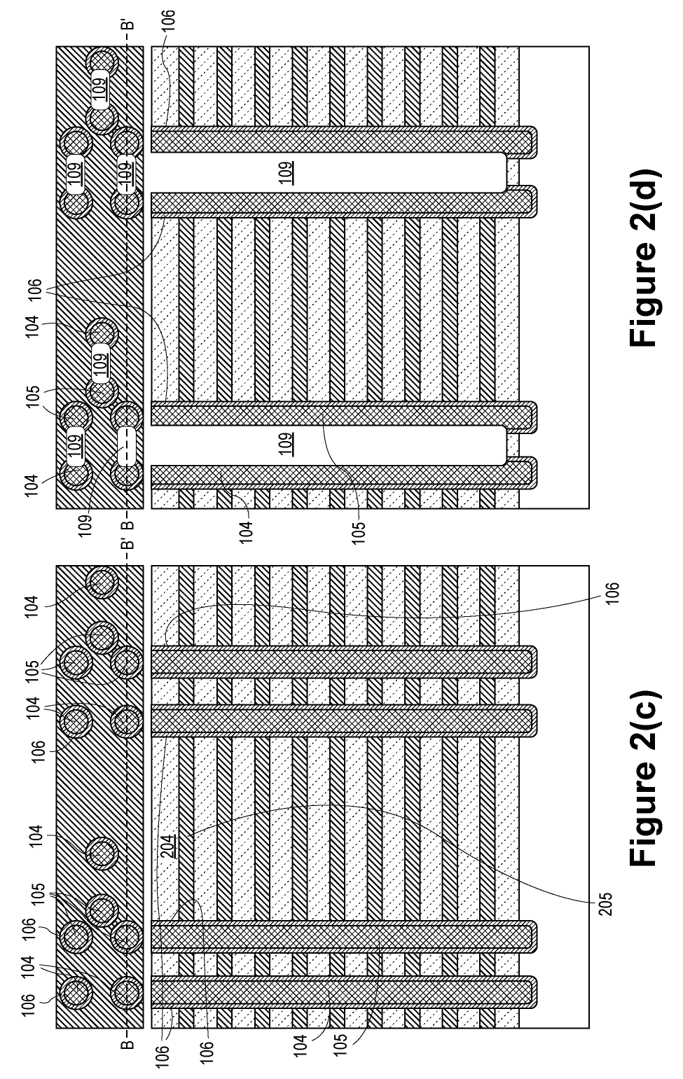

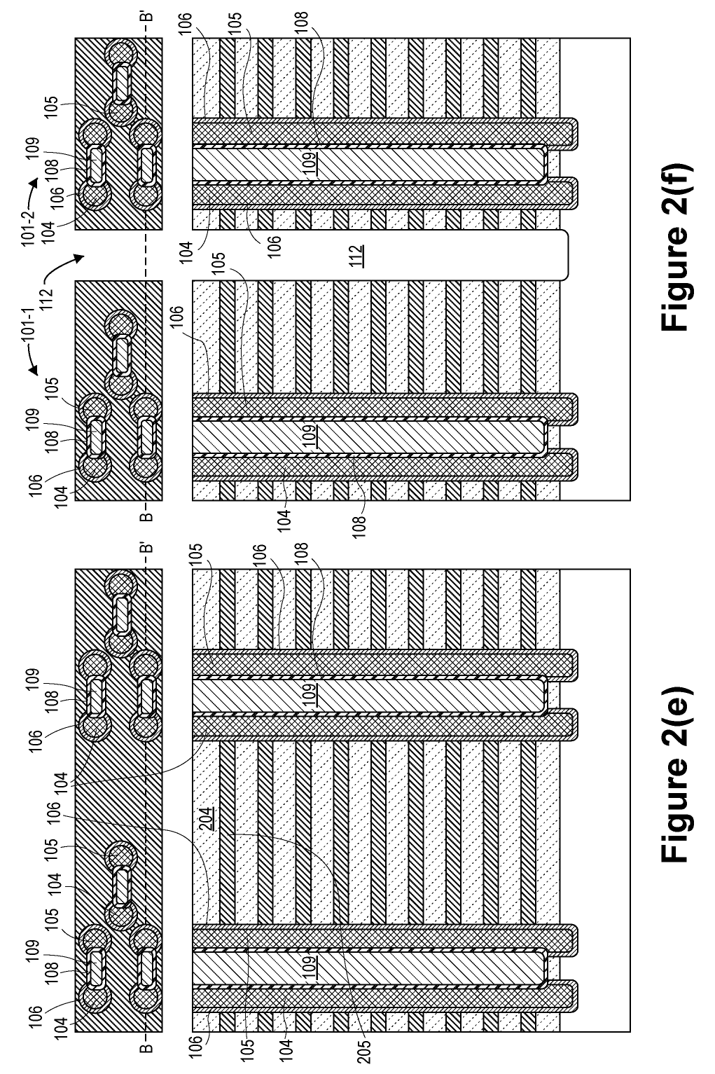

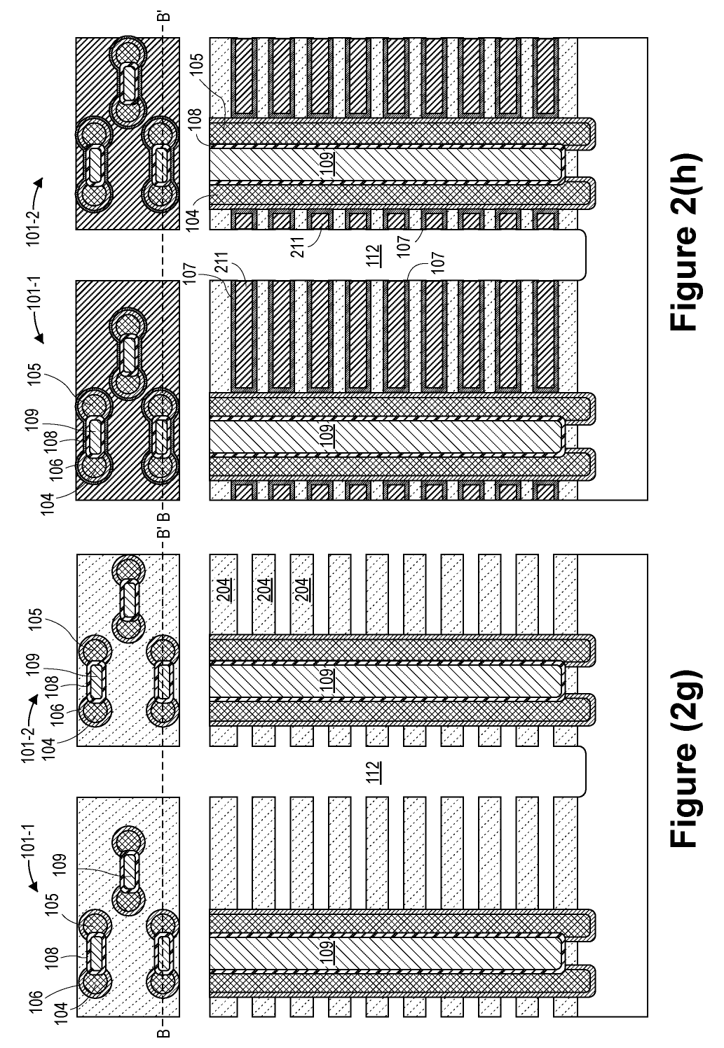

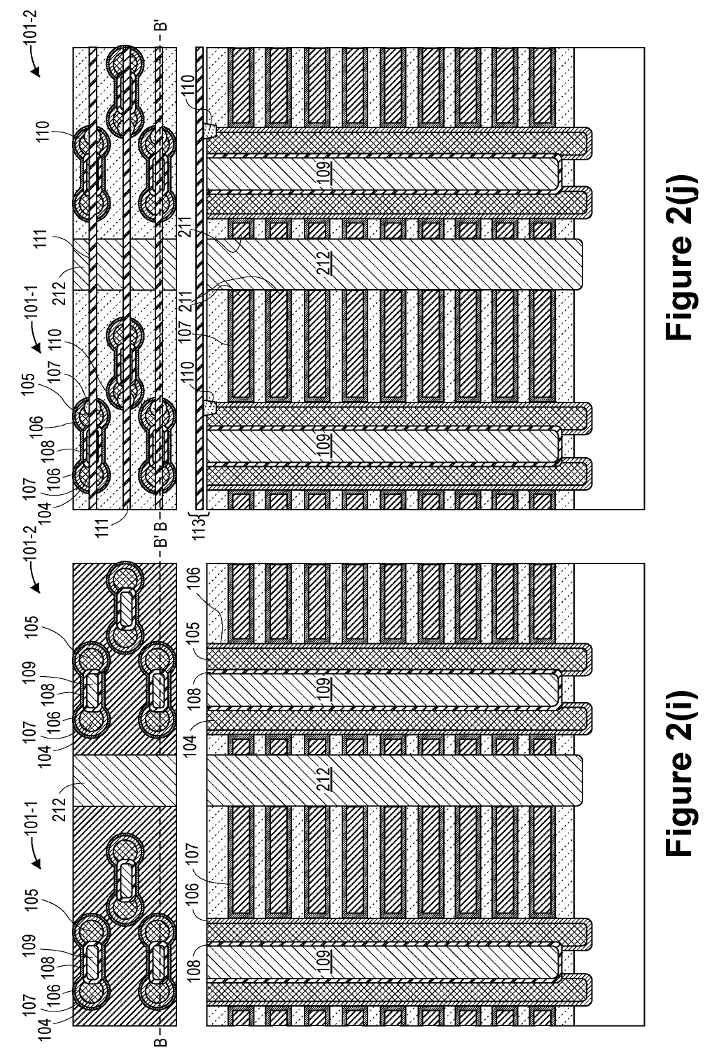

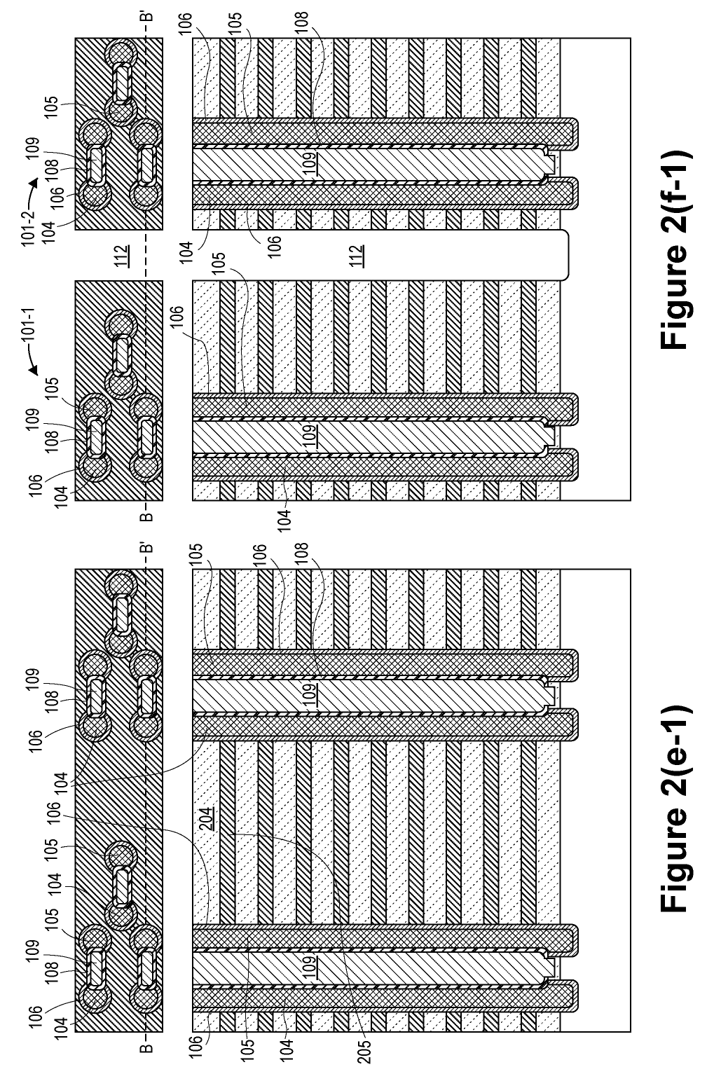

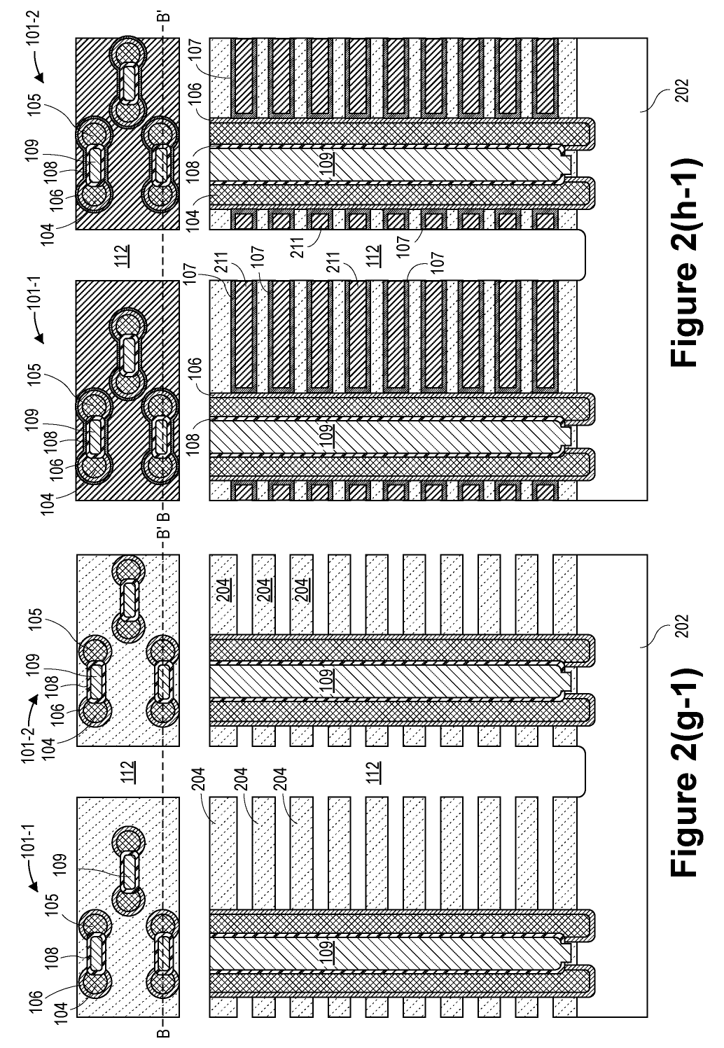

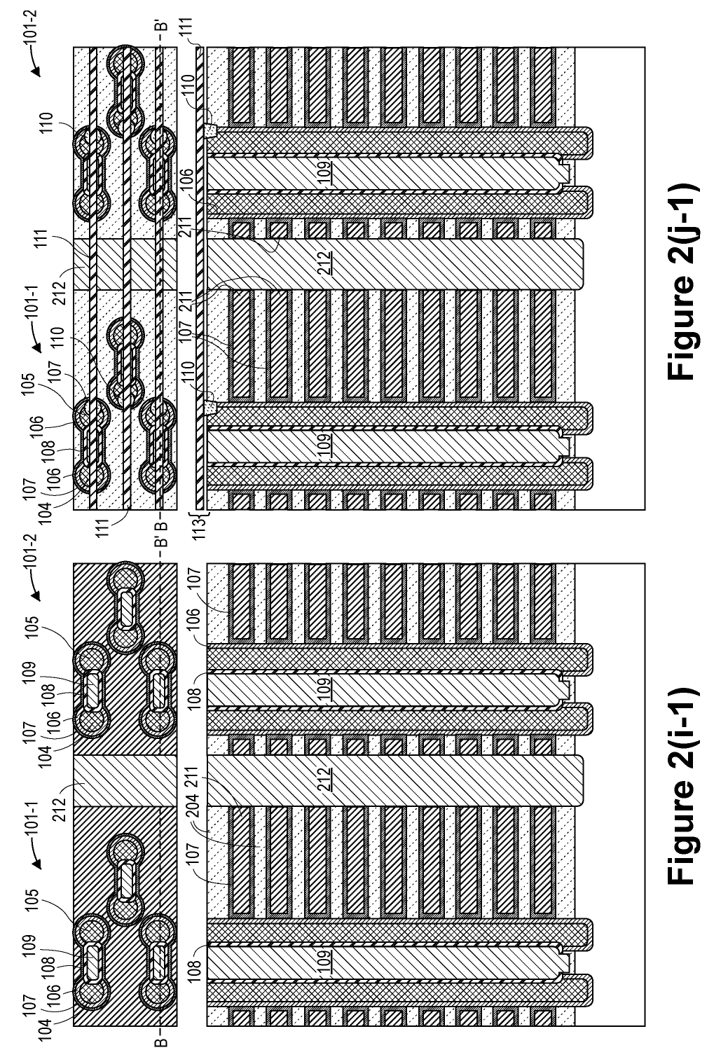

FIGS. 2(a)-2(j) illustrate a process for fabricating modular circuits 101-1 and 101-2, according to one embodiment of the present invention. Each of FIGS. 2(a)-2(j) includes both top view (i.e., X-Y plane) 201-1 and cross-section view (i.e., Z-X plane) 202-2; cross-section view 202-2 is a Z-X plane cross-section along line B-B’ in top view 201-1.

Initially, as shown in FIG. 2(a), alternate layers of silicon oxide 204 and silicon nitride 205 are deposited over the planar surface of semiconductor substrate 202. In some embodiments, prior to depositions of silicon oxide layers 204 and silicon nitride layers 205, circuitry for supporting memory operations has already been formed at or near the planar surface of semiconductor substrate 202. Such circuitry may include, for example, various voltage sources, sense amplifiers, error detection and correction circuitry, registers, latches, and various other logic circuits. Silicon nitride layers 205 serve as sacrificial layers, which are each to be replaced at a subsequent step by a conductor (e.g., tungsten (W) with a titanium nitride (TiN) adhesive liner).

Thereafter, as shown in FIG. 2(b), successive oxide and nitride etches create source and drain shafts 206, each having a diameter, for example, of 100 nm. In some embodiment, a final silicon etch allows the bottoms of source and drain shafts 206 to reach into semiconductor substrate 202.

Insulator layer (e.g., silicon oxide) 106 is then conformally deposited on the sidewalls and the bottom of source and drain shafts 206, which are then filled by n⁺ polysilicon to create n⁺ polysilicon 104 and 105. A chemical-mechanical polishing (CMP) step removes excess the insulator and the n⁺ polysilicon from top oxide layer 204. The resulting structure is shown in FIG. 2(c). In some embodiments, rather than filling source and drain shafts 206 with n⁺ polysilicon, an n⁺ polysilicon liner may be used to line source and drain shafts 206. In that case, source and drain shafts 206 are then filled by a metal (e.g., a tungsten plug) to reduce resistance in the resulting common bit line or the resulting common source line. A chemical-mechanical polishing (CMP) step removes excess insulator and n⁺ polysilicon from the top oxide layer 204.

Successive oxide and nitride etches then create oval channel slots 109, each channel slot having a major axes that is, for example, 100 nm long. Channel slot 109 may reach into the bottom oxide layer 204, as shown in FIG. 2(d).

Conformal layer 108 – either intrinsic polysilicon or p⁻-doped polysilicon -- is then deposited on the sidewalls and the bottom of each of channel slots 109, followed by filling of each channel slot by an insulator material (e.g., silicon oxide). If conformal layer 108 is sufficiently thin, conformal layer 108 can operate as fully depleted channel region even when implemented by intrinsic polysilicon. A CMP step removes excess insulator and p⁻ polysilicon from the top oxide layer 204. The resulting structure is shown in FIG. 2(e).

Slit trenches 112, each 150 nm wide, may then be formed to isolate modular circuits (e.g., modular circuits 101-1 and 101-2) from each other and to facilitate replacement of silicon nitride 205 by a conductor. The resulting structure is shown in FIG. 2(f).

An isotropic silicon nitride etch then removes silicon nitride layers 205, facilitated by slit trenches 112. A trim step (e.g., an oxide trim step) then removes part of silicon oxide layers 204 to ensure that space vacated by silicon nitride layers 205 is sufficiently cleared for conductor replacement (e.g., by TiN-lined W layers), taking care that insulator layer 106 on the sidewalls of n⁺ polysilicon pillars 104 and 105 is not removed. The resulting structure is shown in FIG. 2(g).

Thereafter, storage layer (e.g., an ONO charge-trapping layer) 107 is conformally deposited. TiN liner is then conformally deposited over storage layer 107. Conductor (e.g., metallic tungsten) 211 then fills the space vacated by silicon nitride layers 205 -- forming the word lines -- as well as all or part of slit trenches 112. An anisotropic etch-back step then removes the conductor from slit trenches 112 and to separate the word lines. The resulting structure is shown in FIG. 2(h).

Slit trenches 112 are then filled with insulator material (e.g., silicon oxide) 212 using, for example, a shallow trench fill technique. Excess oxide on the surface may then be removed by CMP. The resulting structure is shown in FIG. 2(i). Isolation layer (e.g., a silicon oxide layer) 113 is then deposited. Conductor-filled vias 110 are then created in isolation layer 113 to contact n⁺ polysilicon pillars 105 (i.e., those n⁺ polysilicon pillars designated to serve as the common bit lines of the VNOR memory strings). Conductors 111 in an interconnection conductor layer over isolation layer 113 are then formed to provide global bit lines to connect the common bit lines of the VNOR memory strings. The resulting structure is shown in FIG. 2(j). In some embodiments, prior to depositing isolation layer 113, top oxide layer 204 is etched back and an etch-stop layer may be provided. The-etch stop layer prevents conductor filled-vias 110 from being formed sufficiently deep as to short via connections 110 to the top conductor layer 211 of the word lines.

In some embodiments, to reduce leakage in the p⁻ polysilicon at the bottom of each of channel slots 109, a layer of liner oxide is deposited by atomic layer deposition (ALD) on the p⁻ polysilicon, so as to protect the p⁻ polysilicon on the sidewalls (i.e., the p⁻ polysilicon designated for channel regions). Then, an anisotropic etch step removes the ALD liner at the bottom of each of channel slots 109, followed by a wet etch that removes the p⁻ polysilicon at the bottom of the channel slot. FIGS. 2(e-1) to 2(j-1) show the alternative structures for the structures shown in FIGS. 2(e) to 2(j).

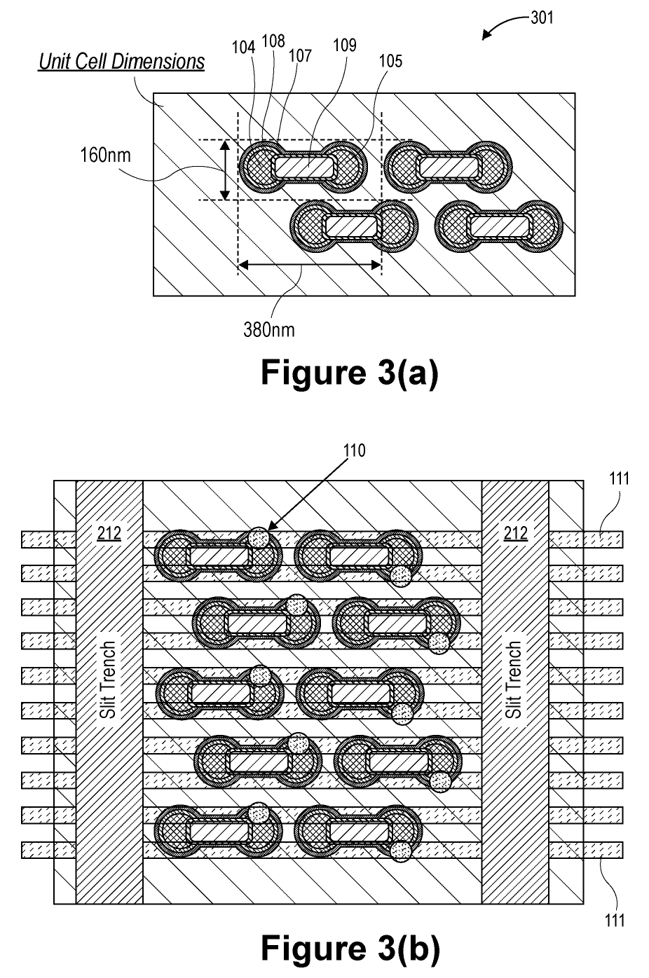

FIG. 3(a) shows top view of unit cell 301, including four VNOR memory strings, according to an alternative embodiment of the present invention. In one embodiment, each VNOR memory string in unit cell 301 may be served by up to 96 word lines. As shown in FIG. 3(a), each VNOR memory string extends 380 nm along the X-direction and 160 nm along the Y-direction, with adjacent rows offset from each other by 80 nm along the X-direction. FIG. 3(b) shows top view of modular circuit 302 having 140 nm wide slit trenches 112 and 40-nm wide conductors 111 serving as global bit lines, contacting each VNOR memory string at a 60-nm diameter conductor-filled via.

The above detailed description is provided to illustrate specific embodiments of the present invention and is not intended to be limiting. Numerous variations and modifications within the scope of the present invention are possible. The present invention is set forth in the accompanying claims.

1. A process for forming a VNOR memory string over a planar surface of a semiconductor substrate, comprising:
providing multiple composite layers, each composite layer comprising an insulator layer and a sacrificial layer;
excavating first and second shafts in the composite layers;
lining the sidewalls of the first and second shafts with a second insulator; filling the first and second shafts with a first semiconductor material of a first conductivity type;
excavating a slot through the composite layers between the first and second shafts, the excavating removing a portion of the first semiconductor material in each of the first and second shafts;
lining the slot conformally with a second semiconductor material of a second conductivity type opposite the first conductivity type;
filling the slot with a third insulator;
creating a trench through the multiple composite layers;
removing the sacrificial layer through the trench to create a space between adjacent insulator layers in the composite layers;
lining the space between the adjacent insulator layers with a conformal storage layer; and
filling the space between the adjacent insulator layers with a conductor.

2. The process of claim 1, wherein the insulator layers in the composite layers, the second insulator, and the third insulator each comprise silicon oxide.

3. The process of claim 1, wherein the first semiconductor material and the second semiconductor material comprise n⁺ polysilicon and p⁻ polysilicon, respectively.

4. The process of claim 1, wherein the storage layer comprises a charge-trapping layer.

5. The process of claim 4, wherein the charge-trapping layer comprises a silicon oxide layer, a silicon nitride layer and a silicon oxide layer.

6. The process of claim 1, wherein the conductor comprises metallic tungsten (W) in conjunction with a titanium nitride (TiN) liner.

7. The process of claim 1, further comprising filling the trench with a fourth insulator.

8. The process of claim 1, further comprising:
providing an isolation layer over the first and second shafts; and
forming a conductor-filled via in the isolation layer, the conductor-filled via contacting one of the first and second shafts.

9. The process of claim 8, further comprising providing on the isolation layer a conductor that is in contact with the conductor-filled via.

10. The process of claim 8, further comprising, prior to forming conductor-filled via, providing an etch-stop layer above a conductor layer in the composite layers between adjacent insulator layers.

11. The process of claim 1, further comprising, after removing the sacrificial layers in the composite layers, removing a portion of each insulator layer in the composite layers to expand room in space vacated by removal of the sacrificial layers of the composite layers.

12. The process of claim 1, wherein, prior to filling the slot with the third insulator, providing a liner insulator on the sidewalls of the second semiconductor material.

13. The process of claim 12, further comprising removing the second semiconductor material at the bottom of the slot.

14. The process of claim 1, wherein excavating the first and second shafts are carried out such that the first and second shafts each reach into the semiconductor substrate.

15. The process of claim 1, wherein excavating the slot is carried out such that the slot reach into the insulator layer of the composite layers closest to the planar surface of the semiconductor substrate.

16. The process of claim 1, wherein, prior to providing the composite layers, forming circuitry for supporting memory operations at or near the planar surface of semiconductor substrate.
